(19) United States
(12) Patent Application Publication
(10) Pub. No.: US 2011/0147947 A1
(43) Pub. Date: Jun. 23, 2011

(54) SEMICONDUCTOR DEVICE AND METHOD FOR FABRICATING THE SAME

(75) Inventor: Shutetsu KANAYAMA, Osaka (JP)

(73) Assignee: PANASONIC CORPORATION, Osaka (JP)

(21) Appl. No.: 13/037,730

(22) Filed: Mar. 1, 2011

Related U.S. Application Data
(63) Continuation of application No. PCT/JP2009/005273, filed on Oct. 9, 2009.

(30) Foreign Application Priority Data
Jan. 20, 2009 (JP) 2009-009982

(51) Int. Cl. H01L 23/48; H01L 21/28

(52) U.S. Cl. 257/774; 438/627; 257/E23.011; 257/E21.158

(57) ABSTRACT

A semiconductor device includes an ELK film formed on a semiconductor substrate, a SiN film formed on the ELK film, and a plurality of interconnects formed in the ELK film and the SiN film to be located substantially at an equal height. The plurality of interconnects are provided in a non-dense interconnect region having a first interconnect area ratio which indicates a ratio of an area occupied by the interconnects per unit area, and a dense interconnect region having a second interconnect area ratio which is higher than the first interconnect area ratio. A height of an upper surface of a part of the SiN film located in the dense interconnect region is lower than a height of an upper surface of a part of the SiN film located in the non-dense interconnect region.

### CROSS-REFERENCE TO RELATED APPLICATION

This is a continuation of PCT International Application PCT/JP2009/005273 filed on Oct. 9, 2009, which claims priority to Japanese Patent Application No. 2009-9982 filed on Jan. 20, 2009. The disclosures of these applications including the specifications, the drawings, and the claims are hereby incorporated by reference in their entirety.

### BACKGROUND

The present disclosure relates to a semiconductor device and a method for fabricating the semiconductor device, and more particularly to a semiconductor device using a porous, low-dielectric-constant insulating film as an interlayer dielectric including buried interconnects and a method for the fabricating the semiconductor device.

In recent years, with the miniaturization and increase in speed of semiconductor devices, there have been an increased number of semiconductor devices using a multilayered interconnect structure. However, with such miniaturization and increase in speed of semiconductor devices and the trend of using a multilayered interconnect structure, signal delays caused by increase in interconnect resistance, parasitic capacitance between interconnects, and parasitic capacitance between interconnect layers become problems. Specifically, because a signal delay T is proportional to the product of an interconnect resistance R and a parasitic capacitance C, in order to reduce the signal delay T, it is necessary to reduce the parasitic capacitance as well as the resistance of interconnect layers.

To reduce the interconnect resistance R, a material having a lower resistance may be used as a material for interconnects. For example, conventional aluminum (Al) interconnects may be replaced with copper (Cu) interconnects.

There is a relationship C=(ε·S)/d among the parasitic capacitance C between interconnect layers, a relative dielectric constant c of an interlayer dielectric provided between the interconnect layers, a distance d between the interconnect layers, and a side surface area S of the interconnected layers. Therefore, to reduce the parasitic capacitance C, it is necessary to use a low-dielectric-constant insulating film (hereinafter referred to as a “low-k film”) as an interlayer dielectric.

Damascene is used in forming copper interconnects using a low-k film (see, e.g., Japanese Patent Publication No. 2002-270586). Damascene is known as a technique for forming interconnects, in which in consideration that control of the etching rate is difficult in etching of copper, as compared to etching of aluminum, etching of copper is not performed. Specifically, in the damascene process, an etching stopper film, a low-k film, and a cap film are formed in this order on a lower layer interconnect, dry etching is performed using a resist film as a mask to form interconnect trenches, the resist film is removed by ashing, and then, a copper layer is filled in the interconnect trenches, thereby forming a copper interconnect layer. To obtain a buried copper layer, a copper layer is formed by plating to fill in and cover the interconnect trenches, and then, a surface of the copper layer is planarized using chemical mechanical polishing (CMP) so that only parts of the copper layer located in the interconnect trenches are left.

### SUMMARY

However, when an extreme low-k (ELK) film is used as an interlayer dielectric for interconnects in a single layer structure, a surface of the ELK film is directly polished in a CMP step for forming buried interconnects. In this step, a serious problem arises in which due to mechanical damage caused by polishing and film damage on film caused by penetration of ingredients of a chemical solution and moisture into the film in cleaning after polishing, the reliability of interconnects is reduced.

Therefore, to ensure low dielectric constant and high reliability using an ELK film, there have been proposed methods in which a low-k film (having a relative dielectric constant of about 3.0, and hereinafter referred to as a “dielectric protection layer (DPL) film”) having a high film density is provided on the ELK film to prevent reduction in reliability due to CMP damage.

However, the present inventor found, as a result of study of actual cross sections of interconnects after CMP, that, in a dense interconnect region where Cu interconnects are densely formed, the DPL film is excessively polished by CMP, so that the ELK film thereunder is exposed.

For example, as shown in FIG. 15A illustrating a cross-sectional structure immediately before CMP is performed, a plurality of interconnect trenches are formed in located in a non-dense interconnect region A and a dense interconnect region B of an ELK film 102 and a DPL film 103 formed on a semiconductor substrate 101, and a copper plated film 104 is formed on the DPL film 103 as well as the interconnect trenches with a barrier metal film 105 interposed therebetween.

Thereafter, as shown in FIG. 15B illustrating a cross-sectional structure after CMP, in the dense interconnect region B, a step (so-called erosion) with a step amount C is caused.

In view of the above-described problems, it is therefore an objective of the present disclosure to reduce erosion caused in a dense interconnect region in which multiple ones of interconnects formed in an interlayer dielectric having a small relative dielectric constant are densely located, thereby preventing exposure of the interlayer dielectric having a small relative dielectric constant.

To achieve the above-described objective, according to the present disclosure, in a semiconductor device, a first insulating film is provided to serve as an interlayer dielectric, and a second insulating film and a third insulating film are provided on the first insulating film so that the first interlayer dielectric is not exposed in a dense interconnect region.

Specifically, a semiconductor device according to the present disclosure includes a first insulating film formed on a semiconductor region, a second insulating film formed on the first insulating film, and a plurality of interconnects formed in the first insulating film and the second insulating film to be located substantially at an equal height, the plurality of interconnects are provided in a first interconnect region having a first interconnect area ratio which indicates a ratio of an area occupied by the interconnects per unit area, and a second interconnect region having a second interconnect area ratio which is higher than the first interconnect area ratio, and a height of an upper surface of a part of the second insulating film located in the second interconnect region is lower than a height of an upper surface of a part of the second insulating film located in the first interconnect region.

In the semiconductor device of the present disclosure, the height of the upper surface of the part of the second insulating film located in the second interconnect region is lower than the height of the upper surface of the part of the second insulating film located in the first interconnect region. That is, in the second interconnect region which is a dense interconnect region, the part of the second insulating film is left, and the first insulating film is not exposed. Therefore, even when an ELK film is used as the first insulating film, the ELK film is not exposed.

In the semiconductor device of the present disclosure, the second interconnect area ratio may be 20% or more and 90% or less.

In the semiconductor device of the present disclosure, a height of a lowest part of the upper surface of the part of the second insulating film located in the second interconnect region may be lower than the height of the upper surface of the part of the second insulating film located in the first interconnect region by 1% or more and 99% or less of a thickness of the second insulating film.

In the semiconductor device of the present disclosure, the height of the lowest part of the upper surface of the part of the second insulating film located in the second interconnect region may be lower than the height of the upper surface of the part of the second insulating film located in the first interconnect region by 1 nm or more and 10 nm or less.

In the semiconductor device of the present disclosure, a third insulating film may be formed between the first insulating film and the second insulating film.

In this case, it is preferable that the third insulating film has a higher dielectric constant than that of the first insulating film.

In the semiconductor device of the present disclosure, the first insulating film may have a higher porosity than that of the second insulating film.

In the semiconductor device of the present disclosure, it is preferable that the first insulating film has a lower dielectric constant than that of the second insulating film.

In the semiconductor device of the present disclosure, it is preferable that the first insulating film has a dielectric constant of 2.7 or less.

In the semiconductor device of the present disclosure, it is preferable that the second insulating film contains nitrogen.

In the semiconductor device of the present disclosure, it is preferable that the second insulating film is made of silicon nitride, silicon carbonitride, or silicon oxynitride.

In the semiconductor device of the present disclosure, the second insulating film may have a thickness equal to 1% or more and 20% or less of that of the first insulating film.

In the semiconductor device of the present disclosure, the second insulating film may have a thickness of 20 nm or less.

A method for fabricating a semiconductor device according to the present disclosure includes the steps of (a) forming a first insulating film, a second insulating film, and a third insulating film in this order on a semiconductor region, (b) forming a plurality of interconnect trenches in the first insulating film, the second insulating film, and the third insulating film, (c) forming a metal film on the third insulating film as well as the interconnect trenches, (d) removing a part of the metal film formed on the third insulating film, and (e) removing the third insulating film to form a plurality of interconnects made of the metal film filled in the interconnect trenches formed in the first insulating film and the second insulating film, and, in the step (e), the third insulating film is removed at a removal rate greater than a removal rate of the second insulating film.

According to the method of the present disclosure, the third insulating film formed on the second insulating film is removed, thereby forming a plurality of interconnects made of metal filled in the interconnect trenches in the first insulating film and the second insulating film. Since the third insulating film is removed at a greater removal rate than a removal rate at which the second insulating film is removed, the second insulating film serves as a stopper film when the third insulating film is removed. Thus, the first insulating film is not exposed.

The method of the present disclosure may further include, between the step (b) and the step (c), the step (f) of forming a barrier metal film on the third insulating film as well as the interconnect trenches, in the step (c), the metal film may be formed on the barrier metal film, and the step (d) may include also removing a part of the barrier metal film located on the third insulating film.

In the method of the present disclosure, the plurality of interconnects may be provided in a first interconnect region having a first interconnect area ratio which indicates a ratio of an area occupied by the interconnects per unit area, and a second interconnect region having a second interconnect area ratio which is higher than the first interconnect area ratio, and a height of an upper surface of a part of the second insulating film located in the second interconnect region may be lower than a height of an upper surface of a part of the second insulating film located in the first interconnect region.

In this case, the second interconnect area ratio may be 20% or more and 90% or less.

Also, in this case, a height of a lowest part of the upper surface of the part of the second insulating film located in the second interconnect region may be lower than the height of the upper surface of the part of the second insulating film located in the first interconnect region by 1% or more and 99% or less of a thickness of the second insulating film.

Furthermore, in this case, the height of the lowest part of the upper surface of the part of the second insulating film located in the second interconnect region may be lower than the height of the upper surface of the part of the second insulating film located in the first interconnect region by 1 nm or more and 10 nm or less.

It is preferable that the third insulating film has a thickness equal to or greater than a difference between the height of the upper surface of the part of the second insulating film located in the first interconnect region and the height of the lowest part of the upper surface of the part of the second insulating film located in the second interconnect region.

In the method of the present disclosure, it is preferable that a value of a ratio of a polishing rate of the third insulating film to a polishing rate of the second insulating film is 50 or more.

In the method of the present disclosure, it is preferable that, in the step (e), the third insulating film is removed by chemical mechanical polishing, and polishing stops at the second insulating film.

In this case, the chemical mechanical polishing can be performed using a ceria slurry.

In this case, a concentration of ceria particles in the ceria slurry may be 1 wt % or more and 3 wt % or less, and a concentration of a surfactant which is an additive in the ceria slurry may be 2 wt % or more and 4 wt % or less.

In the method of the present disclosure, the step (a) may include forming a fourth insulating film between the first insulating film and the second insulating film.

In the method of the present disclosure, the first insulating film may have a higher porosity than that of the second insulating film.

In the method of the present disclosure, the third insulating film may have a higher dielectric constant than that of the first insulating film.

In the method of the present disclosure, it is preferable that the first insulating film has a lower dielectric constant than that of the second insulating film.

In the method of the present disclosure, it is preferable that the first insulating film has a dielectric constant of 2.7 or less.

In the method of the present disclosure, it is preferable that the second insulating film contains nitrogen.

In the method of the present disclosure, it is preferable that the second insulating film is made of silicon nitride, silicon carbonitride, or silicon oxynitride.

In the method of the present disclosure, the second insulating film may have a thickness equal to 1% or more and 20% or less of that of the first insulating film.

In the method of the present disclosure, the second insulating film may have a thickness of 20 nm or less.

In the method of the present disclosure, it is preferable that the third insulating film contains oxygen.

A semiconductor device according to the present disclosure and a method for fabricating the semiconductor device allows reduction in erosion generated in a dense interconnect region where multiple ones of interconnect formed in an interlayer dielectric having a small relative dielectric constant are densely provided. Thus, prevention of exposure of the interlayer dielectric having a small relative dielectric constant is allowed, so that low dielectric constant and high reliability of an interconnect layer can be ensured.

### BRIEF DESCRIPTION OF THE DRAWINGS

FIG. 1 is a partial cross-sectional view illustrating a part of an interconnect layer in a semiconductor device according to a first embodiment of the present disclosure.

FIGS. 2A-2C are partial cross-sectional views illustrating respective steps for fabricating a semiconductor device according to the first embodiment.

FIGS. 3A and 3B are partial cross-sectional views illustrating respective steps for fabricating a semiconductor device according to the first embodiment.

FIG. 4 is a graph showing the relationship between the amount of erosion in a dense interconnect region and the interconnect area ratio after ceria CMP according to the first embodiment, and the relationship therebetween after conventional CMP process.

FIG. 5 is a graph showing the relationship between film thickness and dielectric constant for different materials used for a cap film provided on an ELK film.

FIG. 6A is table showing comparison results of advantages of the semiconductor device of the first embodiment and a conventional semiconductor device in terms of dielectric constant and reliability. FIG. 6B is a cross-sectional view schematically showing the region for which an effective dielectric constant keff was calculated.

FIG. 7 is a graph showing the relationship between a polishing pressure and a polishing rate in polishing using a ceria slurry according to the semiconductor device fabrication method of the first embodiment.

FIGS. 8A-8C are cross-sectional views schematically illustrating polishing mechanism of the ceria slurry in polishing according to the semiconductor device fabrication method of the first embodiment.

FIG. 9 is a graph showing the relationship between a SiO₂ film and erosion of an initial step (after barrier CMP) when the ceria slurry is used in the semiconductor device fabrication method of the first embodiment.

FIG. 10 is a graph showing a necessary film thickness for a SiO₂ film in ceria CMP in the semiconductor device fabrication method of the first embodiment.

FIG. 11 is a partial cross-sectional view illustrating an interconnect layer in a semiconductor device according to a second embodiment of the present disclosure.

FIGS. 12A-12C are partial cross-sectional views illustrating respective steps for fabricating a semiconductor device according to the second embodiment.

FIGS. 13A-13C are partial cross-sectional views illustrating respective steps for fabricating a semiconductor device according to the second embodiment. FIG. 13B is a partial cross-sectional view illustrating a central part of a wafer, and FIG. 13C is a partial cross-sectional view illustrating an end part of the wafer.

FIG. 14 is a graph showing the amount of over-polishing for the central part and the end part of the wafer in the semiconductor device fabrication method of the second embodiment.

FIGS. 15A and 15B are partial cross-sectional views illustrating an interconnect layer in a conventional semiconductor device for the purpose to describe problems that the present disclosure is to solve.

### DETAILED DESCRIPTION

### First Embodiment

A first embodiment of the present disclosure will be described with reference to the accompanying drawings.

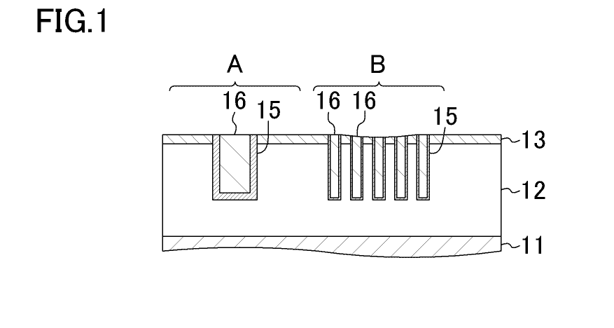

FIG. 1 is a view of a semiconductor device according to the first embodiment of the present disclosure, and shows a partial cross-sectional structure illustrating a single interconnect layer. Note that materials and numerical values of diameters of components, etc., shown in this embodiment are merely preferable examples, and the present disclosure is not limited to this embodiment. This embodiment can be modified in any appropriate fashion without departing from the technical scope of the present disclosure. Furthermore, this embodiment may be combined with other embodiments.

As shown in FIG. 1, in the semiconductor device of the first embodiment, an ELK film 12 having a thickness of about 100 nm and a silicon nitride (SiN) film 13 having a thickness of about 20 nm are formed as an interlayer dielectric on a semiconductor substrate (semiconductor region) 11 made of, e.g., silicon (Si). In this case, the ELK film 12 is a porous film, and can be obtained by forming a methyl silsesquioxane (MSQ) film to which an appropriate pore-forming material (e.g., porogen) is added on the semiconductor substrate 11, and then, removing the pore-forming material by thermal treatment or plasma treatment to introduce a large number of pores in the MSQ film. Thus, a relative dielectric constant of the ELK film 12 can be reduced to be 2.7, or even smaller than 2.7, i.e., about 2.5.

The thickness of the SiN film 13 is preferably larger than 0 nm, and equal to or less than about 20 nm. Note that a silicon carbonitride (SiCN) or silicon oxynitride (SiON) can be used, instead of silicon nitride (SiN).

In the SiN film 13 and the ELK film 12, a plurality of interconnect-forming trenches formed to pass through the SiN film 13 to extend in the ELK film 12 are filled with copper (Cu), and thus, interconnects 16 made of Cu are formed. In this case, a barrier metal film 15 made of, e.g., tantalum nitride (TaN) and tantalum (Ta) and having a thickness of about 15 nm is provided at bottom and wall surfaces of each of the interconnect-forming trenches to be interposed between the interconnects 16 and the ELK film 12 and the SiN film 13.

Note that each of the interconnects 16 formed in a non-dense interconnect region A and a dense interconnect region B is connected to a semiconductor element, a capacitor element, or a resistor element, etc., (not shown) formed on the semiconductor substrate 11 to form a semiconductor integrated circuit with those elements. In this case, as the semiconductor integrated circuit, a device of the 32 nm or less node process design rule is assumed, and the width of the interconnect-forming-trenches in the dense interconnect region B of FIG. 1 is about 50 nm or less.

As a feature of the first embodiment, the height of an upper surface of the SiN film 13 is lower in the dense interconnect region B than in other parts of the SiN film 13 by about 1 nm or more and about 10 nm or less.

Furthermore, the lowest part of the upper surface of the SiN film 13 located in the dense interconnect region B is lower than the height of the upper surface of the other parts of the SiN film 13 by about 1% or more and about 99% or less of the thickness of the SiN film 13.

Thus, according to the first embodiment, erosion in the dense interconnect region B where the multiple ones of the interconnects 16 are densely formed in the ELK film 12 having a small relative dielectric constant can be reduced, and exposure of the ELK film 12 can be prevented, so that the low dielectric constant and high reliability of the interconnects 16 can be ensured.

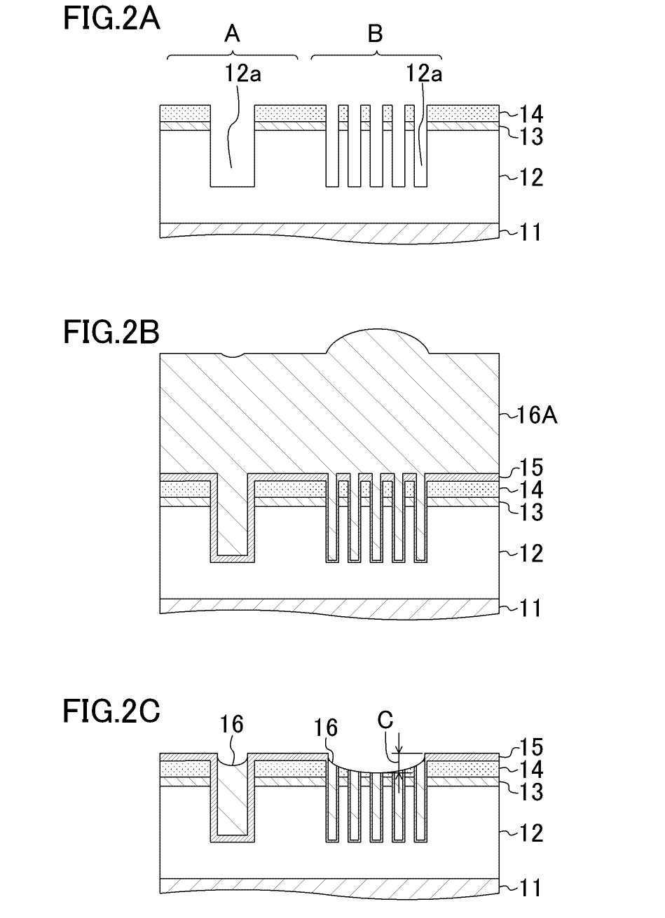

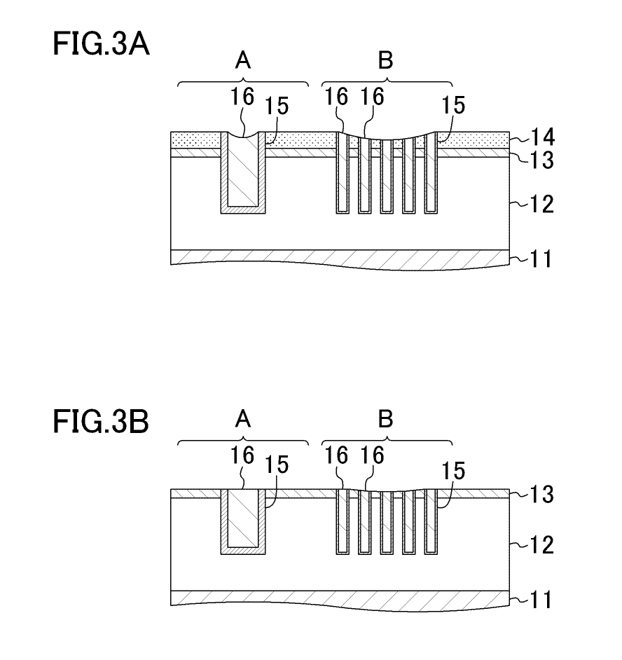

A method for fabricating the semiconductor device having the above-described configuration, specifically, a method for forming interconnects will be hereinafter described with reference to FIGS. 2A-2C and FIGS. 3A and 3B.

First, as shown in FIG. 2A, an ELK film 12, a SiN film 13, and a silicon dioxide (SiO₂) film 14 having a thickness of 60 nm are formed in this order on a semiconductor substrate 11. Thereafter, a plurality of interconnect-forming-trenches 12a are formed to pass through the SiO₂ film 14 and the SiN film 13 and extend in the ELK film 12.

Next, as shown in FIG. 2B, a barrier metal film 15 is formed on the SiO₂ film 14 as well as the interconnect-forming-trenches 12a. Subsequently, a seed Cu film (not shown) which serves as a seed layer in electrolytic plating of copper is deposited. Then, a copper plated film 16A is deposited on the barrier metal film 15 as well as the interconnect-forming-trenches 12a by electrolytic plating, and annealing is performed at a temperature of about 100° C. to 400° C. to join the seed Cu film and the copper plated film 16A together.

Next, as shown in FIG. 2C, an unnecessary part of the copper plated film 16A deposited on the barrier metal film 15 is removed by polishing using chemical mechanical polishing (CMP), thereby forming a plurality of interconnects 16 from the copper plated film 16A. This CMP step will be hereinafter referred to as Cu-CMP. In the dense interconnect region B after the Cu-CMP step, a step, which is called erosion, is generated. A step amount C of erosion varies depending on CMP process. In the 32 nm node process design rule, the step amount C is about 40 nm to 60 nm in the dense interconnect region B where the copper interconnect area ratio is 90%.

Next, as shown in FIG. 3A, CMP is performed again to polish and remove an unnecessary part of the barrier metal film 15 deposited on the SiO₂ film 14. This CMP step of removing the barrier metal film 15 will be referred to as barrier CMP. The step amount C of erosion generated in the dense interconnect region B after the barrier CMP step is reduced by an amount of a polished portion of the barrier metal film 15.

In a conventional method for fabricating a semiconductor device using copper interconnects, CMP process is completed by performing two-stage polishing steps, i.e., Cu-CMP step and barrier CMP step. However, according to the present disclosure, as shown in FIG. 3B, after the barrier CMP, the SiO₂ film 14 is removed by polishing (referred to as ceria CMP) using a ceria slurry to which particles comprised of cerium dioxide (CeO₂) are added.

Thus, erosions respectively generated by Cu-CMP and barrier CMP are substantially eliminated by polishing the SiO₂ film 14. In the ceria CMP, polishing of the SiO₂ film 14 by CMP automatically stops because the polishing rate selectivity between the SiO₂ film 14 and the SiN film 13 located under the SiO₂ film 14 is high. In this case, not to leave the SiO₂ film 14 on the SiN film 13, over-polishing has to be performed. Thus, as long as CMP is used, it is unavoidable that erosion is generated again in the dense interconnect region B. However, when ceria CMP of this embodiment is used, the re-generation of erosion can be reduced, and thus, the step amount C of a generated step is about 10 nm in a region where the interconnect area ratio is 90%. The existence of such pattern dependence is the evidence that CMP has been performed. Thus, eventually, the interconnects 16 made of copper can be formed without having the ELK film 12 exposed, and thus, highly reliable interconnects 16 can be obtained, and a final step can be reduced, or minimized.

Now, the relationship between the interconnect pattern dependency of CMP and the dielectric constant of an interlayer dielectric will be specifically described with reference to results of experiments conducted by the present inventor.

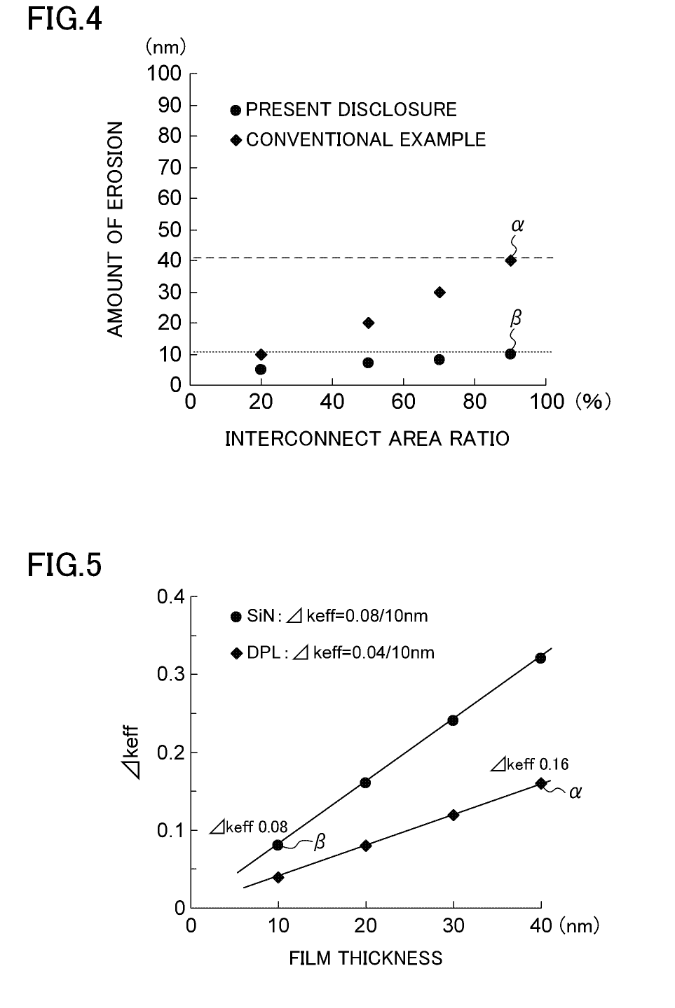

FIG. 4 shows the relationship between the amount of erosion in the dense interconnect region B after ceria CMP according to the first embodiment and the interconnect area ratio, as compared to the case where conventional CMP process was performed. In FIG. 4, for the conventional CMP process, the amount of erosion after completing Cu-CMP and barrier CMP is shown, and the amount of erosion increases as the interconnect area ratio increases. Specifically, the numerical value of the amount of erosion is 40 nm in a region where the interconnect area ratio is 90%. In general, in semiconductor device fabrication, the interconnect area ratio of 90% or more is not used as a design rule, and therefore, data obtained when the interconnect area ratio is 90% may be used in evaluation. The amount of erosion after ceria CMP of this embodiment shows a trend that the step is maximal in the region where the interconnect area ratio is 90%, and the numerical value of the maximal step is about 10 nm.

Conditions for polishing used in the first embodiment are shown in Table 1.

TABLE 1

| | Pressure | Number of Rotations | Flow Rate of Slurry |
|---|---|---|---|
| | (kPa) | (rpm) | (ml/min) |
| Cu-CMP | 13.8 | 103 | 200 |
| Barrier CMP | 13.8 | 83 | 200 |
| Ceria CMP | 20.7 | 53 | 200 |

Next, influences of a step generated due to erosion on the dielectric constant of the interlayer dielectric will be described with reference to FIG. 5.

FIG. 5 shows the relationship between film thickness and dielectric constant for different materials used for a cap film provided on an ELK film.

As the cap film, a DPL film is used in a conventional structure, and a SiN film is used in this embodiment. Results of an examination of increase in thickness and the amount of increase in dielectric constant for both films are: Δkeff=0.04/10 nm for the DPL film, and Δkeff=0.08/10 nm for the SiN film.

Next, respective necessary thicknesses of the cap films in the conventional structure and this embodiment are discussed in terms of structure design. As shown in FIG. 4, a thickness equal to or larger than the amount of erosion in the region where the interconnect area ratio is 90%, i.e., where the step is maximal, is necessary to prevent exposure of the ELK film. Thus, in the conventional example, the necessary thickness is 40 nm, indicated by α in FIG. 4 and FIG. 5, and Δkeff is 0.16. On the other hand, according to this embodiment, based on FIG. 4, the amount of erosion is 10 nm in the region where the interconnect area ratio is 90%, and therefore, the amount of increase in effective dielectric constant can be reduced to Δkeff=0.08, indicated by β of FIG. 5.

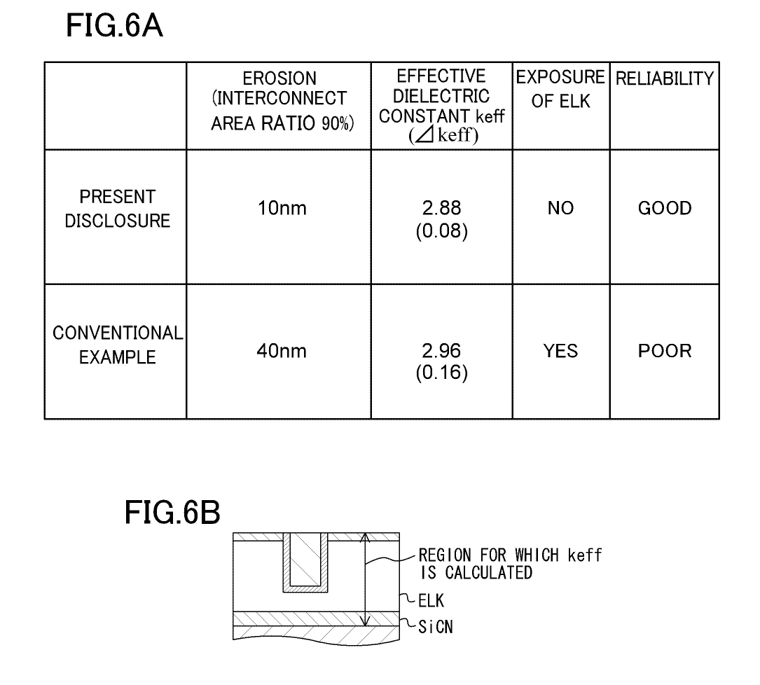

Based on the foregoing, results of comparison of advantages of this embodiment and the conventional example in terms of dielectric constant and reliability are shown in FIGS. 6A and 6B. In this case, to calculate an effective dielectric constant of the entire interconnects, a case where an ELK film having a relative dielectric constant of 2.4 was used as an interconnect structure, and a SiCN film having a relative dielectric constant of 0.4 was used as an etching stopper film therefore was assumed. Then, respective values (k values) of the effective dielectric constants in this embodiment and the conventional example were calculated, and the calculated values were compared. As a result, as shown in FIG. 6A, k=2.88 was obtained for this embodiment, and k=2.96 was obtained for the conventional example. This shows that the semiconductor device according to the present disclosure is more advantageous in terms of effective dielectric constant. In the conventional example, the ELK film is exposed, i.e., there is a problem in terms of reliability. On the other hand, in this embodiment, the ELK film 12 is not exposed, and thus, the reliability is not reduced. Also in this point, the semiconductor device according to this embodiment has greater advantages. Note that FIG. 6B shows the region for which an effective dielectric constant keff was calculated.

Based on the foregoing, the interconnect structure and CMP process according to this embodiment are effective for semiconductor devices of the 32 nm node process design rule. Then, polishing process in ceria CMP, which is a feature of this embodiment, will be hereinafter described in detail.

The present inventor focused on high step-reduction performance of the ceria slurry, which is a feature of the ceria slurry, and high selectivity to silicon nitride (SiN), and introduced the ceria slurry as an etchant in CMP process used for forming an interconnect structure. Then, as a result of examinations conducted by the inventor, the inventor found that great advantages can be achieved by using the ceria slurry.

The ceria slurry has a structure in which a surfactant, serving as ligands, is added, ends of slurry particles are modified by cerium oxide, and a compound such as organic acid, etc., is coordinated around the slurry particles. One of the features of the ceria slurry that level-difference-reduction performance is high, and this feature is achieved because the ceria slurry has a structure in which ligands exist around ceria particles and the ligands surrounding the particles cannot be removed unless a certain pressure is applied. Because of this structure, when a pressure over a certain threshold is applied to the ceria slurry, ligands are removed and particles are exposed, so that the polishing rate is rapidly improved.

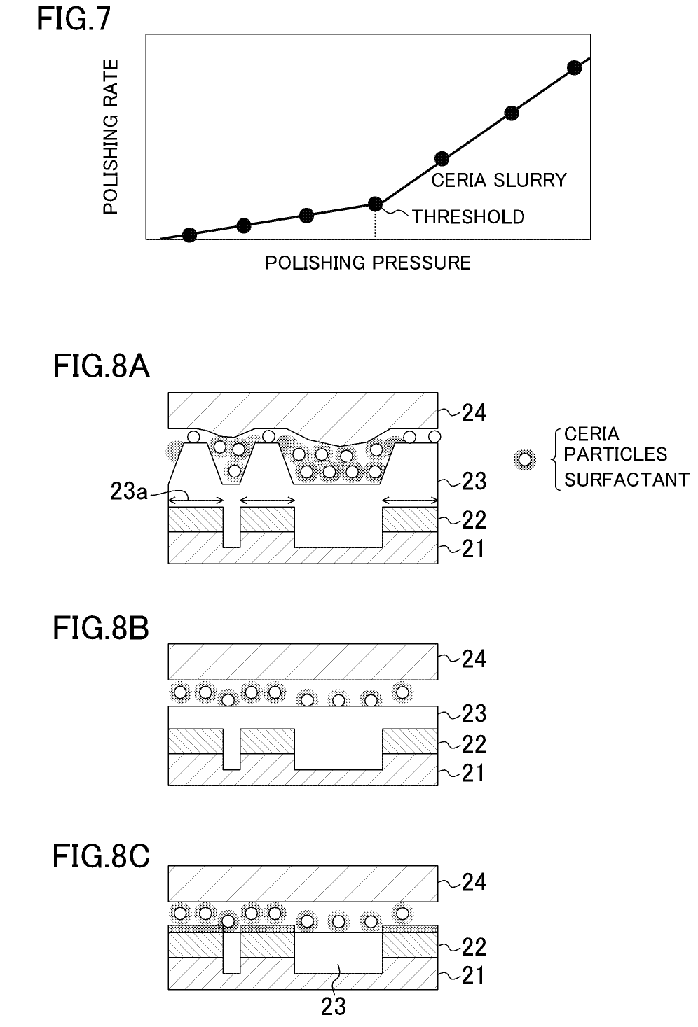

This series of steps are schematically illustrated in FIG. 7 and FIGS. 8A-8C. FIG. 7 shows the relationship between polishing pressure and polishing rate. As shown in FIG. 7, the polishing rate is rapidly increased in proportional to the polishing pressure by applying a polishing pressure over a certain threshold to the ceria slurry.

Next, with reference to FIGS. 8A-8C, surface flatness and selectivity to a SiN film (nitride film) will be described using, as an example, process for shallow trench isolations (STIs) which are of an element isolating film. FIGS. 8A-8C schematically illustrate a polishing mechanism for polishing using the ceria slurry from a start to an end of the polishing.

FIG. 8A illustrates an initial stage after a start of polishing. A SiO₂ film 23 is deposited to cover trenches selectively formed in a semiconductor substrate 21 and a SiN film 22, and a polishing pad 24 is pressed thereto with the ceria slurry interposed therebetween. In this stage, according to an initial recessed-and-raised shape of the SiO₂ film 23, only raised portions of the SiO₂ film 23 are selectively polished. As described above, this is because ceria particles receive polishing pressure only at the raised potions because of the pressure dependency of the ceria slurry. On the other hand, at recessed portions of the surface of the SiO₂ film 23, ceria particles are protected by the surfactant, which is an additive, and thus, polishing of the recessed portions is prevented.

As shown in FIG. 8B, subsequently, the raised portions of the SiO₂ film 23 are selectively polished, and thus, a step with a recessed-and-raised shape in the SiO₂ film 23 is eliminated, so that planarization is substantially completed.

Next, as shown in FIG. 8C, at an end of polishing, when the SiN film 22 is exposed, the additive is selectively absorbed on the SiN film 22. The reason for this is as follows. A surfactant primarily used as an additive is polyacrylic ammonium salt, etc., and polyacrylic ammonium salt is used in a negatively energized state. In the ceria slurry adjusted to be an acidic atmosphere, the surface of the SiN film 22 is positively energized. Thus, the additive is selectively absorbed on the surface of the SiN film 22, thus preventing the SiN film 22 from being polished. As a result, a high polishing selectivity to the SiN film 22 can be achieved, and polishing of the SiN film 22 stops substantially in an automatic manner.

As described above, with use of the ceria slurry having the above-described features in forming an interconnect layer, a step generated after barrier CMP can be polished with high step-reduction performance, and with use of a SiN film with high selectivity thereto as a polishing stopper film, exposure of the ELK film can be prevented.

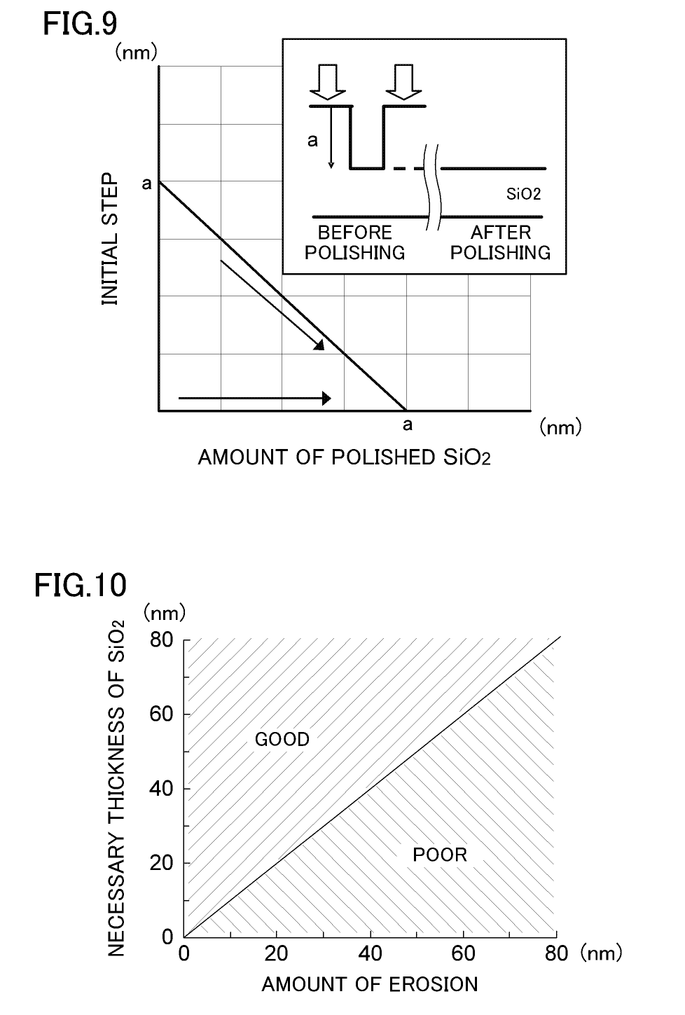

FIG. 9 shows the relationship between a SiO₂ film to be polished when the ceria slurry is used in ceria CMP and an initial step, i.e., erosion after barrier CMP. It is understood from FIG. 9 that when the amount of polished SiO₂ is equal to the initial step, the step is reduced. Therefore, a step with a recessed-and-raised shape can be polished in an ideal manner by using the ceria slurry. Based on the foregoing, the relationship of a necessary thickness of the SiO₂ film for performing ceria CMP and the amount of erosion, i.e., the initial step before polishing is as shown in FIG. 10. That is, as a requirement for the film thickness of the SiO₂ film, the SiO₂ has a thickness equal to or larger than the amount of erosion. In this embodiment, the thickness of the SiO₂ film 14 is 60 nm.

According to this embodiment, as a result of experiments conducted where a sufficient margin is given, when reducing a step, based on the above-described finding that the amount of erosion is about 40 nm in a region where the step after barrier CMP is maximal, i.e., where the interconnect area ratio is 90%, the thickness of the SiO₂ film 14 is set to be 60 nm according to this embodiment. In other words, when the thickness of the SiO₂ film 14 is at least 40 nm, this embodiment is feasible.

Note that as the ceria slurry of this embodiment, a ceria slurry containing ceria particles at a concentration of about 1 wt % or more and 3 wt % or less, and a surfactant as an additive at a concentration of about 2 wt % or more and 4 wt % or less may be used.

The SiO₂ film 14 is a so-called sacrificial film, and may be made of any material as long as a selectivity is obtained between the SiN film 13 and the SiO₂ film 14. Specifically, for example, instead of SiN, carbonitride silicon (SiCN) may be used as a material with which a polishing selectivity of 50 or more can be achieved.

### Second Embodiment

Next, a second embodiment of the present disclosure will be described with reference to the accompanying drawings.

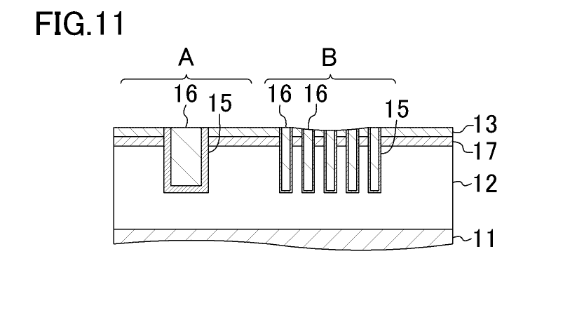

FIG. 11 is a view of a semiconductor device according to the second embodiment of the present disclosure, and shows a partial cross-sectional structure illustrating an interconnect layer in the semiconductor device. Note that materials and numerical values of diameters of components, etc., shown in this embodiment are merely preferable examples, and the present disclosure is not limited to this embodiment. This embodiment can be modified in any appropriate fashion without departing from the technical scope of the present disclosure. In FIG. 11, each member also shown in FIG. 1 is identified by the same reference character, and the description thereof will be omitted.

As shown in FIG. 11, in the second embodiment, a DPL film 17, for example, made of SiO₂ having a thickness of about 10 nm is formed between the ELK film 12 and the SiN film 13.

Note that, also in the second embodiment, each of the interconnects 16 made of copper is connected to a semiconductor element, a capacitor element, or a resistor element, etc., (not shown) formed on the semiconductor substrate 11 to form a semiconductor integrated circuit with those elements.

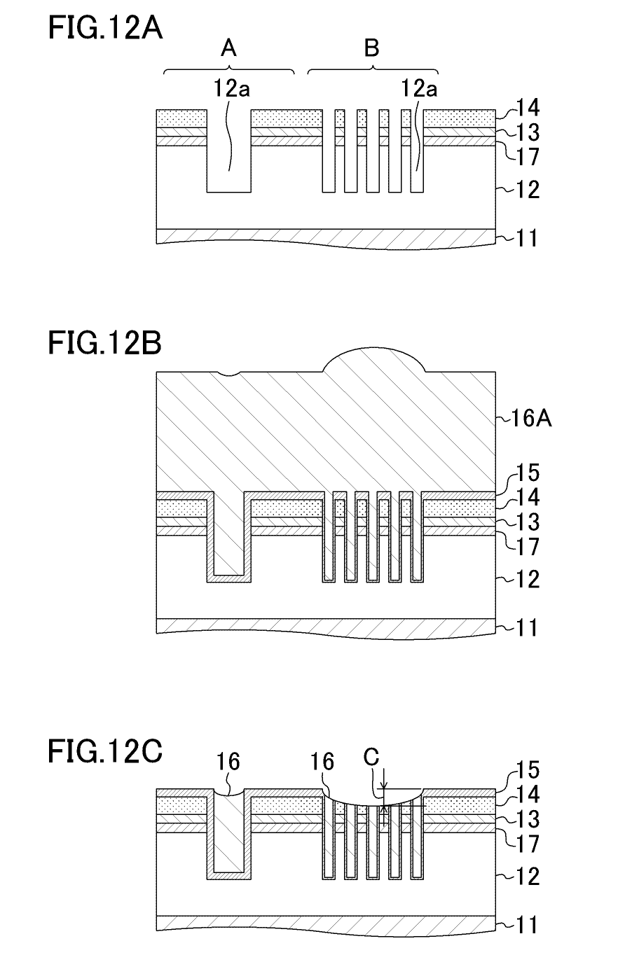

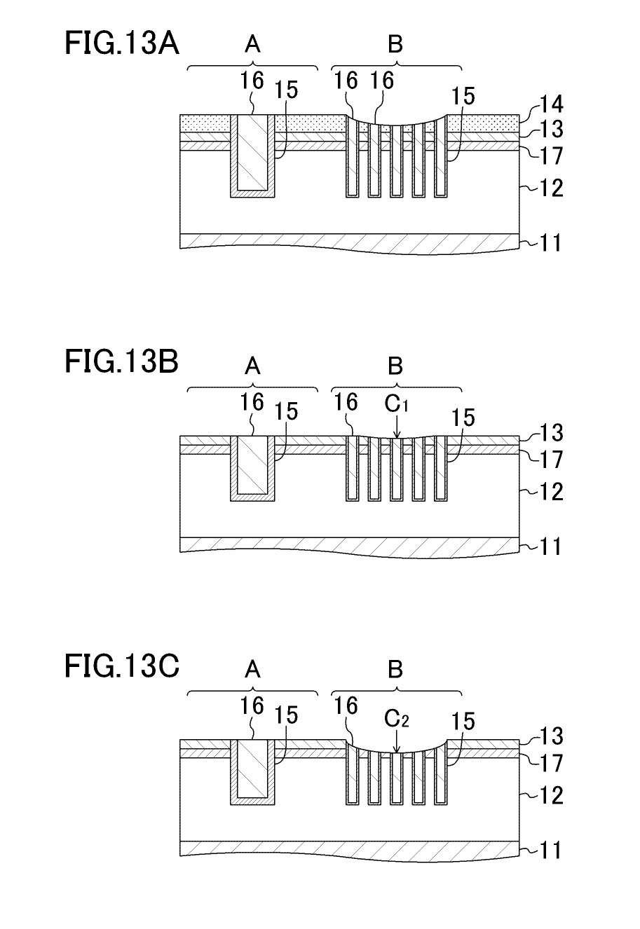

A method for fabricating the semiconductor device having the above-described configuration, specifically, a method for forming interconnects will be hereinafter described with reference to FIGS. 12A-12C and FIGS. 13A and 13B.

First, as shown in FIG. 12A, an ELK film 12, a DPL film 17, a SiN film 13, and a SiO₂ film 14 having a thickness of 60 nm are formed in this order on a semiconductor substrate 11. Thereafter, a plurality of interconnect-forming-trenches 12a are formed in the SiO₂ film 14, the SiN film 13, the DPL film 17, and the ELK film 12.

Next, as shown in FIG. 12B, a barrier metal film 15 is formed on the SiO₂ film 14 as well as the interconnect-forming-trenches 12a. Subsequently, a seed Cu film (not shown) is deposited, and a copper plated film 16A is deposited over the barrier metal film 15 as well as the interconnect-forming-trenches 12a by electrolytic plating. Subsequently, annealing is performed at a temperature of about 100° C. to 400° C. to join the seed Cu film and the copper plated film 16A together.

Next, as shown in FIG. 12C, an unnecessary part of the copper plated film 16A located on the barrier metal film 15 is removed by chemical mechanical polishing (CMP), thereby forming a plurality of interconnects 16 from the copper plated film 16A. In the dense interconnect region B after this Cu-CMP step, erosion with a step amount C is generated. As described above, in the 32 nm node process design rule, the step amount C is about 40 nm to 60 nm in the dense interconnect region B where the copper interconnect area ratio is 90%.

Next, as shown in FIG. 13A, CMP is performed again to polish and remove an unnecessary part of the barrier metal film 15 located on the SiO₂ film 14. As in the first embodiment, the step amount C of erosion generated in the dense interconnect region B after the barrier CMP step is reduced by an amount of a polished portion of the barrier metal film 15.

Next, as shown in FIGS. 13B and 13C, so-called ceria CMP is performed. The necessity of providing the DPL film 17 between the ELK film 12 and the SiN film 13 will be described below in comparison to the first embodiment.

As described above, in ceria CMP, a polishing rate selectivity to the SiN film 13 is high, and thus, the following events hardly occur. However, it is effective to provide the DPL film 17 as one of preventive measures of such events.

Specifically, in CMP process, a slurry is flowed on a wafer, and polishing is mechanically performed. Therefore, when the polishing rate is not uniform in a wafer surface, for example, an end part of the wafer might be excessively polished, as compared to a central part of the wafer. That is, after the SiN film 13 is exposed, the wafer might be over-polished.

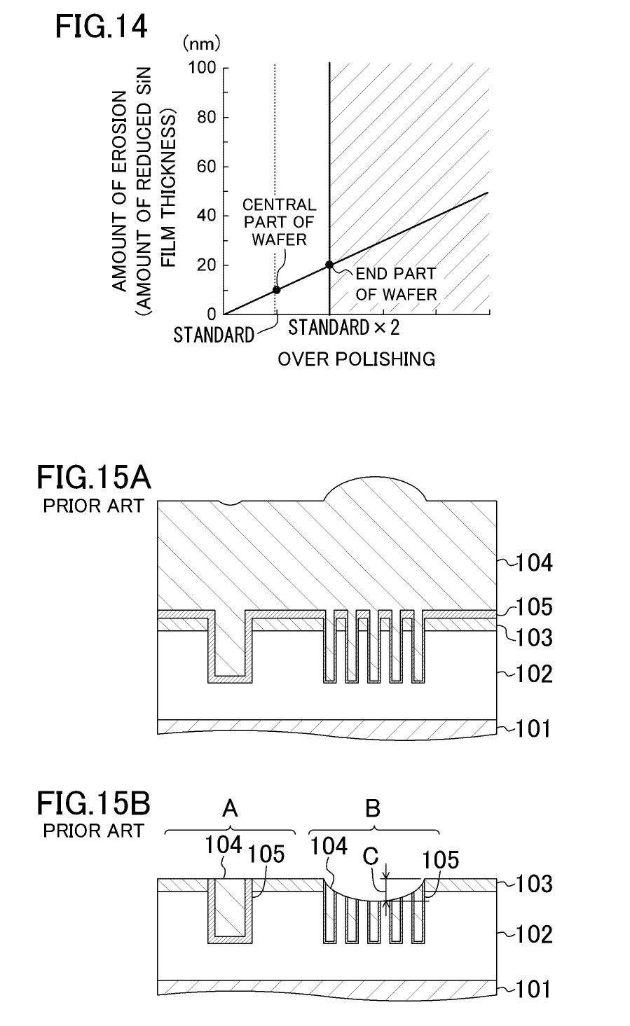

For example, in the central part of the wafer shown in FIG. 13B, polishing stops at the SiN film 13. In contrast, in the end part of the wafer shown in FIG. 13C, polishing does not stop at the SiN film 13 because of over-polishing, so that the DPL film 17 is exposed. Accordingly, a step amount C₂ of erosion in the end part of the wafer shown in FIG. 13C is larger than a step amount C₁ of erosion in the central part of the wafer shown in FIG. 13B. The relationship between the amount of over-polishing and the amount of erosion is shown in FIG. 14.

As shown in FIG. 14, when the amount of over-polishing in the central part of the wafer is assumed to be a standard amount, the amount of over-polishing in the end part of the wafer is twice the standard amount, or more. In this case, the SiN film 13 is not left in a region where a maximal step is, and thus, an underlying layer provided under the SiN film 13 is exposed.

In the second embodiment, the upper surface of the ELK film 12 is covered (capped) by the DPL film 17 to prevent exposure of the ELK film 12. In this case, the thickness of the SiN film 13 is preferably 20 nm or less. This is because, as shown in FIG. 5, considering dielectric constant, when the SiN film 13 is larger than 20 nm, the effective dielectric constant of the entire interconnects 16 can be reduced by using a DPL film of which a dielectric constant increases at a small rate per unit film thickness.

In the second embodiment, it is assumed that a step generated in the end part of the wafer is 21 nm. In this case, the thickness of the SiN film 13 may be 20 nm, the thickness of the DPL film 17 may be 10 nm. Thus, as the amount of increase in dielectric constant in the end part of the wafer, the thickness of 20 nm (Δkeff=0.16) of the SiN film 13 and the thickness of 10 nm (Δkeff=0.04) of the DPL film 17 are added, and Δkeff=0.2 is obtained. The amount of increase in dielectric constant is smaller, as compared to when the SiN film 13 having a thickness of 30 nm (Δkeff=0.24) is used.

As described above, according to the second embodiment, the DPL film 17 is provided between the ELK film 12 and the SiN film 13. Thus, exposure of the ELK film 12 can be reliably prevented even at an end part of a wafer.

A semiconductor device according to the present disclosure and a method for fabricating the semiconductor device allows reduction in erosion generated in a dense interconnect region where multiple ones of interconnect formed in an interlayer dielectric having a small relative dielectric constant are densely provided. Thus, prevention of exposure of the interlayer dielectric having a small relative dielectric constant is allowed, so that low dielectric constant and high reliability of an interconnect layer can be ensured. Therefore, the present disclosure is useful particularly in a semiconductor device using a porous, low dielectric-constant insulating film as an interlayer dielectric including buried interconnects, and a method for fabricating the semiconductor device, etc.

What is claimed is:

1. A semiconductor device, comprising:
a first insulating film formed on a semiconductor region;
a second insulating film formed on the first insulating film; and
a plurality of interconnects formed in the first insulating film and the second insulating film to be located substantially at an equal height,
wherein
the plurality of interconnects are provided in a first interconnect region having a first interconnect area ratio which indicates a ratio of an area occupied by the interconnects per unit area, and a second interconnect region having a second interconnect area ratio which is higher than the first interconnect area ratio, and
a height of an upper surface of a part of the second insulating film located in the second interconnect region is lower than a height of an upper surface of a part of the second insulating film located in the first interconnect region.

2. The semiconductor device of claim 1, wherein
the second interconnect area ratio is 20% or more and 90% or less.

3. The semiconductor device of claim 1, wherein
a height of a lowest part of the upper surface of the part of the second insulating film located in the second interconnect region is lower than the height of the upper surface of the part of the second insulating film located in the first interconnect region by 1% or more and 99% or less of a thickness of the second insulating film.

4. The semiconductor device of claim 1, wherein
a height of a lowest part of the upper surface of the part of the second insulating film located in the second interconnect region is lower than the height of the upper surface of the part of the second insulating film located in the first interconnect region by 1 nm or more and 10 nm or less.

5. The semiconductor device of claim 1, wherein
a third insulating film is formed between the first insulating film and the second insulating film.

6. The semiconductor device of claim 5, wherein
the third insulating film has a higher dielectric constant than that of the first insulating film.

7. The semiconductor device of claim 1, wherein
the first insulating film has a higher porosity than that of the second insulating film.

8. The semiconductor device of claim 1, wherein
the first insulating film has a lower dielectric constant than that of the second insulating film.

9. The semiconductor device of claim 1, wherein
the first insulating film has a dielectric constant of 2.7 or less.

10. The semiconductor device of claim 1, wherein
the second insulating film contains nitrogen.

11. The semiconductor device of claim 1, wherein
the second insulating film is made of silicon nitride, silicon carbonitride, or silicon oxynitride.

12. The semiconductor device of claim 1, wherein
the second insulating film has a thickness equal to 1% or more and 20% or less of that of the first insulating film.

13. The semiconductor device of claim 1, wherein
the second insulating film has a thickness of 20 nm or less.

14. A method for fabricating a semiconductor device, the method comprising the steps of:
(a) forming a first insulating film, a second insulating film, and a third insulating film in this order on a semiconductor region;
(b) forming a plurality of interconnect trenches in the first insulating film, the second insulating film, and the third insulating film;
(c) forming a metal film on the third insulating film as well as the interconnect trenches;
(d) removing a part of the metal film formed on the third insulating film; and
(e) removing the third insulating film to form a plurality of interconnects made of the metal film filled in the interconnect trenches formed in the first insulating film and the second insulating film,
wherein
in the step (e), the third insulating film is removed at a removal rate greater than a removal rate of the second insulating film.

15. The method of claim 14, further comprising:
between the step (b) and the step (c), the step (f) of forming a barrier metal film on the third insulating film as well as the interconnect trenches,
wherein
in the step (c), the metal film is formed on the barrier metal film, and
the step (d) includes also removing a part of the barrier metal film located on the third insulating film.

16. The method of claim 14, wherein
the plurality of interconnects are provided in a first interconnect region having a first interconnect area ratio which indicates a ratio of an area occupied by the interconnects per unit area, and a second interconnect region having a second interconnect area ratio which is higher than the first interconnect area ratio, and
a height of an upper surface of a part of the second insulating film located in the second interconnect region is lower than a height of an upper surface of a part of the second insulating film located in the first interconnect region.

17. The method of claim 16, wherein
the second interconnect area ratio is 20% or more and 90% or less.

18. The method of claim 16, wherein
a height of a lowest part of the upper surface of the part of the second insulating film located in the second interconnect region is lower than the height of the upper surface of the part of the second insulating film located in the first interconnect region by 1% or more and 99% or less of a thickness of the second insulating film.

19. The method of claim 16, wherein
a height of a lowest part of the upper surface of the part of the second insulating film located in the second interconnect region is lower than the height of the upper surface of the part of the second insulating film located in the first interconnect region by 1 nm or more and 10 nm or less.

20. The method of claim 16, wherein
the third insulating film has a thickness equal to or greater than a difference between the height of the upper surface of the part of the second insulating film located in the first interconnect region and the height of the lowest part of the upper surface of the part of the second insulating film located in the second interconnect region.

21. The method of claim 14, wherein
a value of a ratio of a polishing rate of the third insulating film to a polishing rate of the second insulating film is 50 or more.

22. The method of claim 14, wherein
in the step (e), the third insulating film is removed by chemical mechanical polishing, and polishing stops at the second insulating film.

23. The method of claim 22, wherein
the chemical mechanical polishing is performed using a ceria slurry.

24. The method of claim 23, wherein
a concentration of ceria particles in the ceria slurry is 1 wt % or more and 3 wt % or less, and a concentration of a surfactant which is an additive in the ceria slurry is 2 w t% or more and 4 wt % or less.

25. The method of claim 14, wherein
the step (a) includes forming a fourth insulating film between the first insulating film and the second insulating film.

26. The method of claim 14, wherein
the first insulating film has a higher porosity than that of the second insulating film.

27. The method of claim 14, wherein
the third insulating film has a higher dielectric constant than that of the first insulating film.

28. The method of claim 14, wherein
the first insulating film has a lower dielectric constant than that of the second insulating film.

29. The method of claim 14, wherein
the first insulating film has a dielectric constant of 2.7 or less.

30. The method of claim 14, wherein
the second insulating film contains nitrogen.

31. The method of claim 14, wherein
the second insulating film is made of silicon nitride, silicon carbonitride, or silicon oxynitride.

32. The method of claim 14, wherein
the second insulating film has a thickness equal to 1% or more and 20% or less of that of the first insulating film.

33. The method of claim 14, wherein
the second insulating film has a thickness of 20 nm or less.

34. The method of claims 14-33, wherein
the third insulating film contains oxygen.
